(19) United States
(12) Patent Application Publication
(10) Pub. No.: US 2025/0218751 A1
(43) Pub. Date: Jul. 3, 2025

(54) REAL-TIME MEASUREMENT OF MICROWAVE RESONATORS AS PLASMA DIAGNOSTICS FOR PROCESS MONITORING

(71) Applicant: Applied Materials, Inc., Santa Clara, CA (US)

(72) Inventors: DAVID PETERSON, San Jose, CA (US); DAVID COUMOU, Webster, NY (US)

(21) Appl. No.: 18/401,112

(22) Filed: Dec. 29, 2023

(51) Int. Cl. H01J 37/32; G01N 22/00

(52) U.S. Cl. CPC H01J 37/32935; G01N 22/00; H01J 37/32192; H01J 2237/24564

(57) ABSTRACT

Embodiments disclosed herein include an apparatus that comprises a board with a signal generator for generating chirped signals on the board. In an embodiment, a first mixer is on the board and electrically coupled to the signal generator, and a circulator is on the board. In an embodiment, the circulator comprises a first port that is electrically coupled to the mixer, a second port that is electrically coupled to a connector, and a third port. In an embodiment, a second mixer is on the board and electrically coupled to the third port of the circulator. In an embodiment, an analog to digital converter (ADC) is on the board and electrically coupled to the second mixer.

### BACKGROUND

### 1) Field

Embodiments relate to the field of semiconductor manufacturing and, in particular, real-time measurement of microwave resonators for plasma diagnostics.

### 2) Description of Related Art

Semiconductor processing environments often use plasma sources. In order to provide highly repeatable and stable processing environments, it is desirable to measure various plasma properties, such as electron density, electron temperature, and the like. In some instances, high density plasmas are used. High density plasmas are particularly difficult to measure with existing metrology tools.

One limitation of existing tools is that real-time measurement of plasmas is inherently difficult to provide. Without the ability to capture real-time information about the plasma conditions, necessary control of process parameters cannot be as accurately maintained. Applications such as chamber matching are also limited in such instances. Current solutions may also be relatively invasive to the processing environment, which makes them unsuitable for high volume manufacturing (HVM).

### SUMMARY

Embodiments disclosed herein include an apparatus that comprises a board with a signal generator for generating chirped signals on the board. In an embodiment, a first mixer is on the board and electrically coupled to the signal generator, and a circulator is on the board. In an embodiment, the circulator comprises a first port that is electrically coupled to the mixer, a second port that is electrically coupled to a connector, and a third port. In an embodiment, a second mixer is on the board and electrically coupled to the third port of the circulator. In an embodiment, an analog to digital converter (ADC) is on the board and electrically coupled to the second mixer.

Embodiments disclosed herein may also comprise a method for monitoring a plasma property in real time. In an embodiment, the method comprises generating a chirped signal with a first frequency range, and converting the first frequency range to a second frequency range that is higher than the first frequency range. In an embodiment, the method further comprises providing the chirped signal to a resonator for interaction with a plasma, where a plasma modified resonant frequency of the resonator is measured by a reflected chirped carrier signal. In an embodiment, the process further comprises converting the reflected signal to a third frequency range that is lower than the second frequency range. In an embodiment, the method further comprises extracting a plasma property from the reflected signal.

Embodiments disclosed herein further comprise a tool. In an embodiment, the tool comprises a chamber suitable for generating a plasma. In an embodiment, the tool further comprises a pedestal within the chamber for supporting a substrate, and a sensor at least partially within the chamber for measuring plasma properties. In an embodiment, the sensor comprises a resonator or a transmission line, and RF circuitry coupled to the resonator. In an embodiment, the RF circuitry is configured to generate chirped pulses that are fed to the resonator.

### BRIEF DESCRIPTION OF THE DRAWINGS

FIG. 1A is a schematic illustration of an apparatus that includes RF circuitry for generating chirped pulses that are up-converted and down-converted for use in measuring plasma properties, in accordance with an embodiment.

FIG. 1B is a schematic illustration of an apparatus that includes RF circuitry for generating chirped pulses that are down-converted for use in measuring plasma properties, in accordance with an embodiment.

FIG. 1C is a schematic illustration of an apparatus that includes RF circuitry for generating chirped pulses that includes a digital domain for some portions of the apparatus, in accordance with an embodiment.

FIG. 2 is a sequential illustration of a chirped pulse as it is up-converted and down-converted for use in measuring plasma properties, in accordance with an embodiment.

FIG. 3 is a plot of a plurality of chirped pulses generated over a duration of time, in accordance with an embodiment.

FIG. 4A is a schematic illustration of RF circuitry for a real-time plasma sensor, in accordance with an embodiment.

FIG. 4B is a schematic illustration of RF circuitry for a real-time plasma sensor, in accordance with an additional embodiment.

FIG. 5A is a cross-sectional illustration of a tool that comprises a plasma chamber and a real-time plasma sensor provided on a wall of the plasma chamber, in accordance with an embodiment.

FIG. 5B is a cross-sectional illustration of a tool that comprises a plasma chamber and a real-time plasma sensor provided on a probe that extends out from a wall of the plasma chamber, in accordance with an embodiment.

FIG. 6 is a plan view illustration of a real-time plasma sensor that is integrated into a substrate that can be placed within a plasma chamber, in accordance with an embodiment.

FIG. 7 is a process flow diagram of a process for measuring a plasma property in real-time with a chirped pulse signal, in accordance with an embodiment.

FIG. 8 is a process flow diagram of a process for measuring a plasma property in real-time with a chirped pulse signal, in accordance with an additional embodiment.

FIG. 9 illustrates a block diagram of an exemplary computer system that may be used in conjunction with a processing tool, in accordance with an embodiment.

### DETAILED DESCRIPTION

Systems described herein include systems for providing real-time measurement of plasma properties using chirped pulse carrier signals. In the following description, numerous specific details are set forth in order to provide a thorough understanding of embodiments. It will be apparent to one skilled in the art that embodiments may be practiced without these specific details. In other instances, well-known aspects are not described in detail in order to not unnecessarily obscure embodiments. Furthermore, it is to be understood that the various embodiments shown in the accompanying drawings are illustrative representations and are not necessarily drawn to scale.

As noted above, plasma diagnostics are limited by several factors. One prominent limiting factor is that real-time monitoring of plasma behavior is not possible with existing sensor solutions, especially when considering implementation in high volume manufacturing (HVM) environments. Currently, a boxcar averaging method is used in order to take time resolved measurements. However, such approaches require a signal for triggering and are inherently delayed. That is, they do not approach “real-time” capabilities. Boxcar solutions may require time durations that are on the order of tenths of a second to one or more seconds. This is particularly problematic in instances where the plasma is pulsed or undergoes other rapid changes.

As used herein, “real-time” monitoring may refer to the monitoring of properties of a plasma (or other form of matter) with minimal delay between the detection of a signal and the output of the measurement. More specifically, “real-time”may refer to a measurement process where a delay between the detection of a signal and the output of the measurement is approximately 10 μs or less, approximately 5.0 μs or less, approximately 1.0 μs or less, or approximately 0.1 μs or less. The real-time sensing provided by embodiments disclosed herein allows for improvements in time resolution of three or more orders of magnitude compared to existing solutions. As used herein, “approximately” may refer to a value that is within ten percent of the stated value. For example, approximately 10 μs may refer to a range between 9.0 μs and 11 μs.

Embodiments disclosed herein are able to provide real-time sensing through the use of electronic circuitry and systems that rely on a pulsed chirp signal. A chirped signal is capable of measuring a large bandwidth in short time periods, (e.g., 10 μs or less). For example, the bandwidth of the chirp may be up to approximately 1 GHz or up to approximately 5 GHz. Accordingly, a broad spectrum can be detected with a single pulse cycle to allow for real-time analysis.

In an embodiment, the sensing system may comprise a resonator that is exposed to the plasma environment. In the case of a resonator, a shift in the resonant frequency of the resonator when exposed to the plasma (as opposed to a vacuum) may be used to measure one or more plasma properties. The resonator may be coupled to electrical circuitry that is configured to generate the chirp and process the resulting signals. While a resonator based plasma monitoring technique may be used in some embodiments, other applications for chirped pulse methods may utilize non-resonator type plasma diagnostic implementations. For example, cutoff probe techniques that includes an electrically conductive transmission line may be used in place of a resonator component. In the case of a cutoff probe, the transmission line may measure a frequency of the plasma in order to calculate one or more plasma properties. In an embodiment, the electrical circuitry may comprise a chirp generator. This allows for rapid monitoring of microwave resonances that can be used as a plasma diagnostic. After the chirped pulse is generated, some additional circuitry (e.g., RF circuitry) may be used to modify the chirped pulse to a suitable carrier frequency. After interacting with the resonator, the reflected chirp pulse is then down-converted and sampled. These circuitry components may be integrated onto a board, such as a motherboard, a printed circuit board (PCB), or the like.

The sensor (including circuitry and resonator) can be integrated into a processing tool in various approaches depending on the needs of the device. In one instance, the sensor can be a wall mounted component on the interior surface of a plasma chamber. Such an embodiment may be suitable for HVM tools. Other embodiments may include mounting the resonator to a probe that extends towards a center of the chamber. Such embodiments may be more suitable for diagnostic or research and development purposes. In yet another embodiment, the sensor may be integrated as a diagnostic wafer (or substrate) that can be passed between tools.

Embodiments disclosed herein may allow for improved process monitoring of plasma conditions and environments. Chamber fingerprinting can also be implemented. As such, improved control of a given process can be implemented in order to improve process uniformity and other metrics. Additionally, when multiple chambers are monitored by sensors, chamber matching processes can be used. The real-time nature of the process monitoring also allows for pulsed plasma conditions to be accurately monitored and controlled.

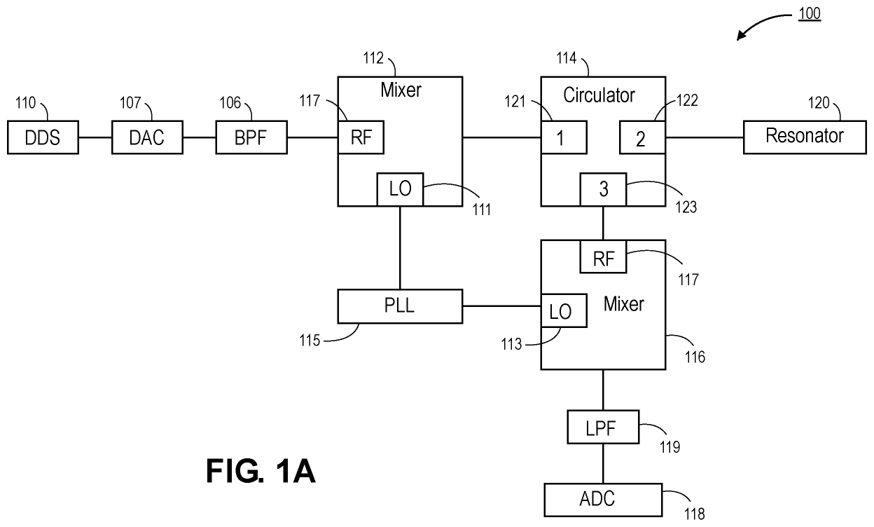

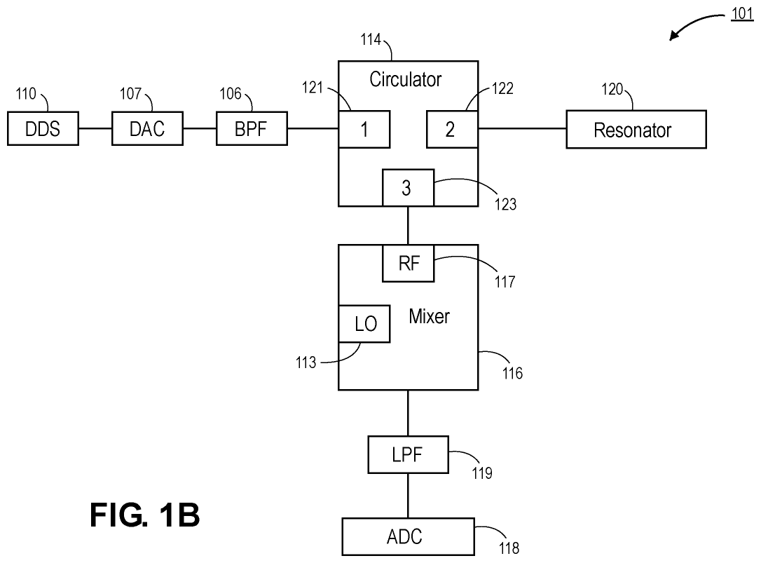

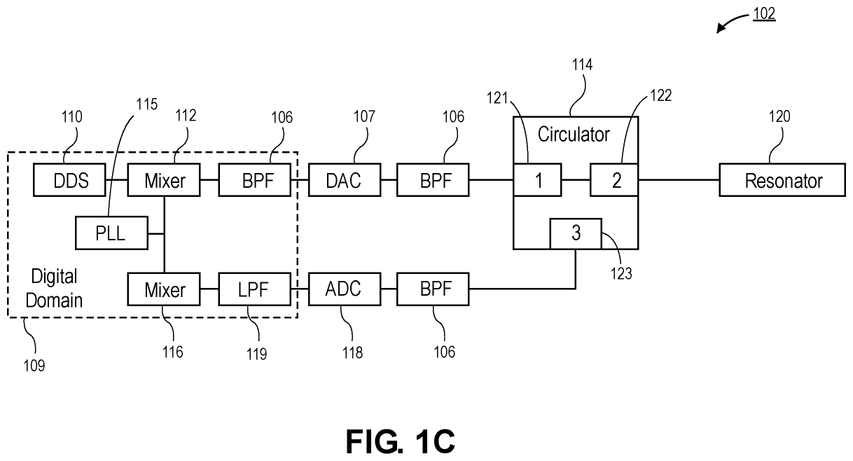

Referring now to FIG. 1A, a schematic illustration of a sensor 100 is shown, in accordance with an embodiment. In an embodiment, the sensor 100 may comprise a resonator 120 that is coupled to associated circuitry. In an embodiment, the circuitry may include RF circuitry. As used herein, components that are described as being “electrically coupled” to each other are components that are connected to each other by electrical circuitry or the like. In some embodiments, the components may be directly connected to each other so that a trace has a first end at a first component and a second end at a second component. In other embodiments, electrically coupled components may have one or more intervening components. For example, a first component may be electrically coupled to a second component with a third component being provided along the electrical path between the first component and the second component.

In an embodiment, the electrical circuitry may comprise a signal generator 110. In order to provide real-time measurements, the signal generator 110 may include the functionality to generate a chirped signal. In an embodiment, the signal generator 110 is capable of signal creation with constant power with time-varying frequency formation at a variable frequency ramp generation time. The chirped signal may have a pulse length of approximately 10 μs or less, approximately 5.0 μs or less, approximately 1.0 μs or less, or approximately 0.1 μs or less. A bandwidth of the chirp may be up to 1.0 GHZ, up to 2.0 GHz, or up to 5.0 GHz. For example, the frequency range of the chirped pulse may be between 0.01 GHz and 1.0 GHz in some embodiments. In an embodiment, the signal generator 110 may include a direct digital synthesizer (DDS).

In an embodiment, the signal generator 110 may be electrically coupled to a first mixer 112. In an embodiment, a digital-analog converter (DAC) 107 and a bandpass filter (BPF) 106 may be provided between the signal generator 110 and the first mixer 112. This allows for a digital signal to be generated by the signal generator 110 that is converted to an analog signal for use in measuring properties of the plasma. Additionally, in some embodiments, a high pass filter (HPF) (not shown) may be provided after the first mixer 112. The first mixer 112 may include an RF port 117 for receiving the chirped signal. In an embodiment, the first mixer 112 is configured to up-convert the chirped pulse to a suitable carrier frequency for subsequent use by the resonator 120. For example, the chirped pulse may have a first frequency range that is converted to a second frequency range by the first mixer 112. The second frequency range may be higher than the first frequency range. For example, when the first frequency range is between 0.01 GHz and 1.0 GHz, the second frequency range may be between 9.01 GHz and 10 GHz.

In an embodiment, the first mixer 112 may be electrically coupled to a circulator 114. The circulator 114 may have three ports 121, 122, and 123. The first port 121 may be electrically coupled to the mixer 112. As such, the modified chirped pulse is delivered to the first port 121. The circulator 114 then propagates the modified chirped pulse to the second port 122. The modified chirped pulse is propagated to the resonator 120 that is electrically coupled to the second port 122 of the circulator 114.

In an embodiment, the resonator 120 may be exposed to a plasma environment. For example, the resonator 120 may be along a sidewall of a plasma chamber (not shown), on a probe within a plasma chamber, or on a wafer that is inserted into the plasma chamber. The resonator 120 may have any suitable architecture in order to interact with the plasma. In a particular embodiment, the resonator 120 may be a half wave probe resonator or other microwave resonator 120 structure. The resonator 120 interacts with the plasma, so that the resonant frequency is dielectrically modified and then detected by the chirped pulse.

In an embodiment, a reflected signal from the resonator 120 passes back to the circulator 114, and the circulator 114 routes the reflected signal to the third port 123. In an embodiment, the circulator 114 is electrically coupled to a second mixer 116. For example, the third port 123 is electrically coupled to an RF port 117 of the second mixer 116. In an embodiment, the second mixer 116 down-converts the chirped pulse back to a frequency range that is more suitable for sampling. For example, the frequency range may be converted back to the original frequency range produced by the signal generator 110. Though, in other embodiments, the frequency range may be any frequency range that is below the frequency range of the chirped pulse after the first mixer 112.

In an embodiment, the first mixer 112 may be electrically coupled to the second mixer 116. For example, a phase locked loop (PLL) synthesizer 115 may be provided between the first mixer 112 and the second mixer 116. The PLL synthesizer 115 may be coupled to a first local oscillator (LO) 111 at the first mixer 112 and a second LO 113 at the second mixer 116. The PLL synthesizer 115 may allow for both mixers to be phase locked in order to allow for improved signal modification at the first mixer 112 and the second mixer 116, and to allow for improved measurement accuracy during frequency recovery.

In an embodiment, the second mixer 116 may be electrically coupled to a sampling component 118. The sampling component 118 may be used in order to extract the frequency of the plasma from the chirped pulse carrier signal. In an embodiment, the sampling component 118 may comprise an analog to digital converter (ADC). The extracted resonant frequency can then be used in order to determine one or more plasma properties. For example, plasma electron density, electron temperature, or the like may be determined by analyzing the resonant frequency. In an embodiment, a LPF 119 may be provided between the second mixer 116 and the sampling component 118 in order to improve the quality of the signal provided to the sampling component 118.

Referring now to FIG. 1B, a schematic illustration of a sensor 101 is shown, in accordance with an additional embodiment. In an embodiment, the sensor 101 may comprise a resonator 120 that is electrically coupled to circuitry. For example, the circuitry may be RF circuitry. In an embodiment, the circuitry may be provided on a board, such as a motherboard, a PCB, or the like.

In an embodiment, the electrical circuitry may comprise a signal generator 110. The signal generator 110 in FIG. 1B may be similar to the signal generator 110 in FIG. 1A, with the exception of the frequency range. Instead of providing a low frequency range (e.g., with an upper frequency of around 1.0 GHz or around 2.0 GHZ), the frequency range may have an upper frequency that is approximately 5 GHz or higher or 10 GHz or higher. For example, the frequency range of the chirped pulse may be between 9.0 GHz and 11.0 GHz. The higher frequency range may allow for the up conversion before the circulator 114 to be eliminated. Instead, the signal generator 110 may be directly coupled to the circulator 114. Though, a DAC 107 and a BPF 106 may be provided between the signal generator 110 and the circulator 114. This allows for a digital signal to be generated by the signal generator 110 that is converted to an analog signal for use in measuring properties of the plasma.

After receiving the chirped pulse signal at the first port 121, the circulator 114 propagates the signal out the second port 122 to the resonator 120. The reflected signal (which incorporates information on plasma properties) is then propagated from the second port 122 to the third port 123 by the circulator 114. In an embodiment, the third port 123 of the circulator 114 is coupled to an RF port 117 of a mixer 116. The mixer 116 may down-convert the signal so that the signal is suitable for sampling by the sampling component 118. The mixer 116 and/or the sampling component 118 in FIG. 1B may be similar to the mixer 116 and/or the sampling component 118 in FIG. 1A. Additionally, it is to be appreciated that the mixer 116 may be optional in some embodiments.

Referring now to FIG. 1C, a schematic illustration of a sensor 102 is shown, in accordance with an additional embodiment. In an embodiment, the sensor 102 may comprise a resonator 120 that is electrically coupled to circuitry. For example, the circuitry may include RF circuitry and a digital domain 109. In an embodiment, the circuitry may be provided on a board, such as a motherboard, a PCB, or the like.

In an embodiment, the digital domain 109 may include the signal generator 110, the first mixer 112, and a BPF 106 as part of the input chain to the circulator 114. A DAC 107 and an additional BPF 106 may also be included between the input chain and the circulator 114 outside of the digital domain 109. Similarly, a portion of the output chain may be integrated into the digital domain 109. For example, after a BPF 106 and an ADC 118, the output chain may continue in the digital domain 109 with a LPF 119 and the second mixer 116. The PLL synthesizer 115 between the first mixer 112 and the second mixer 116 may also be included in the digital domain 109.

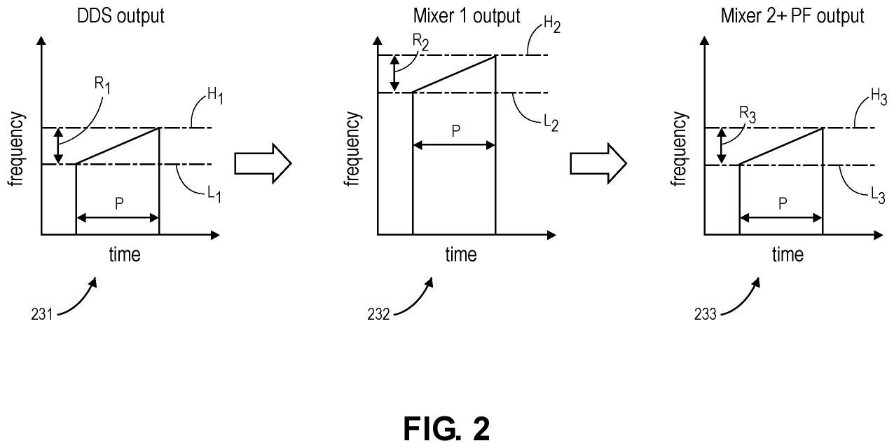

Referring now to FIG. 2, a sequential illustration of a chirped pulse as it passes through the electrical circuitry of the sensor is shown, in accordance with an embodiment. Snapshot 231 is a look at the signal shortly after generation by the signal generator. As shown, the signal may have a pulse length P. For example, the pulse length P may be approximately 10 μs or less, approximately 5.0 μs or less, approximately 1.0 μs or less, or approximately 0.1 μs or less. In an embodiment, the signal may have a first range R₁ with a low frequency L₁ and a high frequency H₁. In an embodiment, the first range R₁ may be between 1.0 GHz and 5 GHz. In an embodiment, the low frequency L₁ may be approximately 0.01 GHz, and the high frequency H₁ may be 1.0 GHz. Though, it is to be appreciated that any first range R₁ with suitable low frequency L₁ and high frequency H₁ may be used in other embodiments.

In the illustrated embodiment, the chirped pulse is shown as being a linear chirp. However, embodiments are not limited to such embodiments. For example, the chirped pulse may also include an exponential chirp, a parabolic chirp, or any other non-linear signal. Also, while chirps with an increasing frequency are shown in FIG. 2, chirps may also include decreasing frequency (i.e., a negative chirp).

Snapshot 232 is a view of the signal after the signal has been modified (e.g., up-converted) after passing through the first mixer. As shown, the second range R₂ is higher than the first range R₁. That is, the high frequency H₂ is higher than the high frequency H₁ and/or the low frequency L₂ is higher than the low frequency L₁. In an embodiment, the bandwidth of the second range R₂ may be similar to the bandwidth of the first range R₁. For example, the second range R₂ may have a bandwidth up to approximately 1 GHz, up to approximately 2 GHZ, or up to approximately 5 GHz. In a particular embodiment, the high frequency H₂ may be approximately 11 GHz, and the low frequency L₂ may be approximately 9 GHz.

Snapshot 233 is a view of the signal after the signal has been modified (e.g., down-converted) after passing through the second mixer. As shown, the third range R₃ is lower than the second range R₂. That is, the high frequency H₃ is lower than the high frequency H₂ and/or the low frequency L₃ is lower than the low frequency L₂. In an embodiment, the bandwidth of the third range R₃ may be similar to the bandwidth of the first range R₁ and/or the bandwidth of the second range R₂. For example, the second range R₂ may have a bandwidth up to approximately 1 GHz, up to approximately 2 GHZ, or up to approximately 5 GHz. In an particular embodiment, the high frequency H₃ and low frequency L₃ may be similar to the high frequency H₁ and the low frequency L₁ of the signal at the first snapshot 231. For example, the high frequency H₃ may be approximately 1.0 GHz, and the low frequency L₃ may be approximately 0.01 GHz.

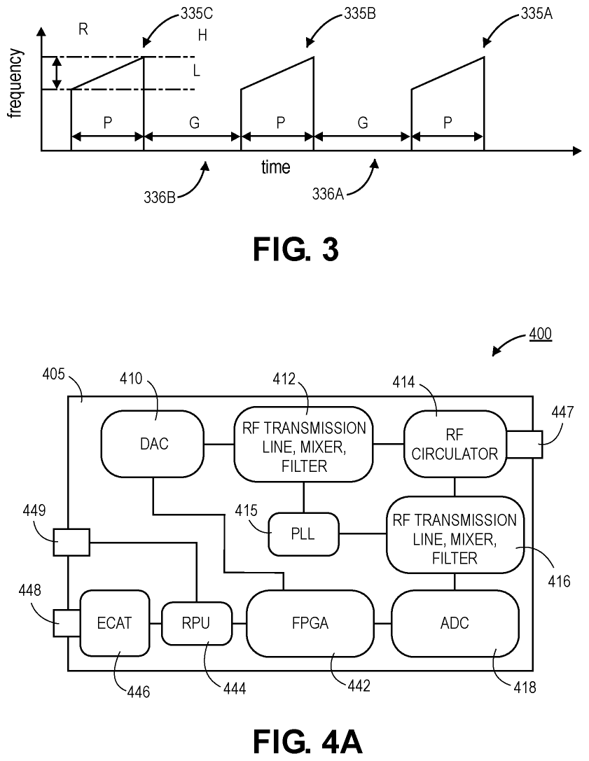

Referring now to FIG. 3, a plot of a plurality of chirped pulse signals 335A-335C generated over a duration of time is shown, in accordance with an embodiment. In an embodiment, the signals 335 may be similar to any of the chirp pulse waveforms described in greater detail herein. The signals 335 may have a pulse duration P that is approximately 1,000 μs or less, 100 μs or less, 10 μs or less, approximately 5.0 μs or less, approximately 1.0 μs or less, or approximately 0.1 μs or less. Though, real-time monitoring may also be applicable with pulse durations P that are up to 100 ms (e.g., 50 ms to 100 ms), in some embodiments. A bandwidth range R of the chirp may be up to 1.0 GHZ, up to 2.0 GHz, or up to 5.0 GHz. For example, the frequency range of the chirped pulse may include a low frequency L that is approximately 0.01 GHz and a high frequency H that is approximately 1.0 GHz in some embodiments.

As shown, the chirped pulse signals 335 may be spaced by a temporal gap G at locations 336A and 336B. In an embodiment, the temporal gap G May be used in order to allow each signal 335 to pass through the system in order to extract useful information about the plasma. In an embodiment, the temporal gap G may have a duration that is similar to the pulse duration P. Though, in other embodiments, the temporal gap G may be greater than or less than the pulse duration P. In some embodiments, the temporal gap G may be between 0.5 μs and 10 μs. In yet another embodiment, the temporal gap G may be omitted. That is, a continuous chirped signal may be used in some embodiments. For example, a first portion of the signal may include an increasing frequency, a second portion of the signal (immediately after the first portion) may include a decreasing frequency, and a third portion of the signal (immediately after the second portion) may include an increasing frequency.

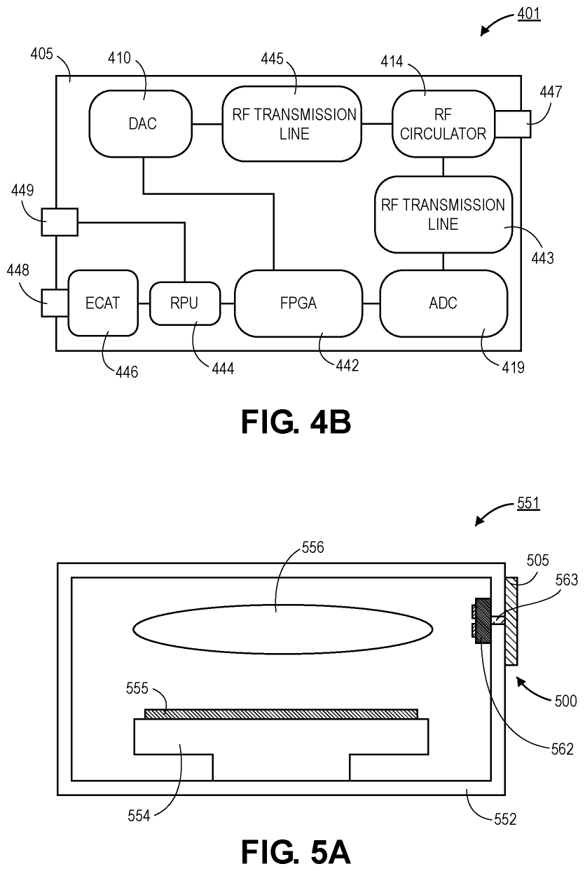

Referring now to FIG. 4A, a plan view illustration of a portion of a sensor 400 is shown, in accordance with an embodiment. The portion of the sensor 400 that is shown includes the electrical circuitry. The resonator that is coupled to the electrical circuitry is omitted for clarity. In an embodiment, the electrical circuitry may be provided on a board 405, such as a motherboard, a PCB, or the like. While a single board 405 is shown, it is to be appreciated that embodiments may integrate the components and circuitry on two or more boards 405.

In an embodiment, the sensor 400 may include a signal generation device 410 on the board 405. The signal generation device 410 may be a digital to analog converter (DAC) or the like. The signal generation device 410 may be suitable for generating chirped pulse signals similar to those described in greater detail herein. In some embodiments, a processor 442 (such as a field programmable gate array (FPGA)) may be responsible (or partially responsible) for generating the chirped waveform. As such, a line connecting the signal generation device 410 to the processor 442 may be used to indicate an input to the signal generation device 410. In an embodiment, the signal generation device 410 may be electrically coupled to a mixer 412. The mixer 412 may also comprise associated filters, transmission lines, and the like. In an embodiment, the mixer 412 converts the chirped pulse signal from the signal generation device 410. For example, the chirped pulse signal may up-convert the signal to a higher frequency range.

In an embodiment, the mixer 412 is coupled to a circulator 414. The circulator 414 may have a port that is coupled to a connector 447. The connector 447 may be any suitable I/O connector architecture for coupling with a resonator. For example, the connector 447 may be a subminiature (SMA) port. After the signal has been propagated to the resonator, interacted with the plasma, and reflected back to the circulator 414, the signal is routed to another mixer 416. The mixer 416 may also comprise associated filters, transmission lines, and the like. In an embodiment, the mixer 416 down-converts the chirped pulse signal down to a frequency range suitable for sampling. In an embodiment, the mixer 416 may be electrically coupled to the mixer 412 through a PLL synthesizer 415.

In an embodiment, the mixer 412 may be coupled to a sampling component 418, such as an ADC. The sampling component 418 may be electrically coupled to a processor 442. For example, the processor 442 may comprise an FPGA that is capable of short-time Fourier transform (STFT) operations and/or Lorentzian fit calculations before subsequent pulses are received (e.g., within 10 μs or less, within 5 μs or less, or within 1 μs or less). A real time processing unit (RPU) 444 may be electrically coupled to the processor 442 to implement some of the processing and/or to improve processing performance. The RPU 444 may be coupled to an interconnect module 446 (e.g., an ECAT module). The interconnect module 446 may include a connector interface 448. The RPU 444 may further be directly coupled to a connector interface 449. The connector interfaces 448 and 449 may provide the data/signals to one or more external devices (not shown) (e.g., a computer, a server, etc.) for controlling or monitoring a plasma process and/or tool. In some embodiments, one or more controllers (not shown) for various components may also be incorporated on and/or in the board 405.

Referring now to FIG. 4B, a plan view illustration of a portion of a sensor 401 is shown, in accordance with an embodiment. The portion of the sensor 401 that is shown includes the electrical circuitry. The resonator that is coupled to the electrical circuitry is omitted for clarity. In an embodiment, the electrical circuitry may be provided on a board 405, such as a motherboard, a PCB, or the like. In an embodiment, the sensor 401 may be similar to the sensor 400 shown in FIG. 4A, with the omission of the mixers (e.g., first mixer 412 and second mixer 416) and the PLL 415. Instead of using mixers, a doubler is used to increase the frequency of the chirped pulse. For example, the frequency may be doubled up to approximately 8.0 GHz. The doubler may be integrated into the processor 442 in order to feed a higher frequency chirp to the DAC. RF transmission lines 445 and 443 may replace the first mixer 412 and the second mixer 416. Such an embodiment may enable pulse durations that are on the shorter end of ranges described herein (e.g., 1.0 μs or less, or 0.5 μs or less). Shorter pulses may allow for higher measurement bandwidths or improved measurement time resolution. However, the sampling component 418 may need to have increased performance in order to accommodate the faster sampling rate.

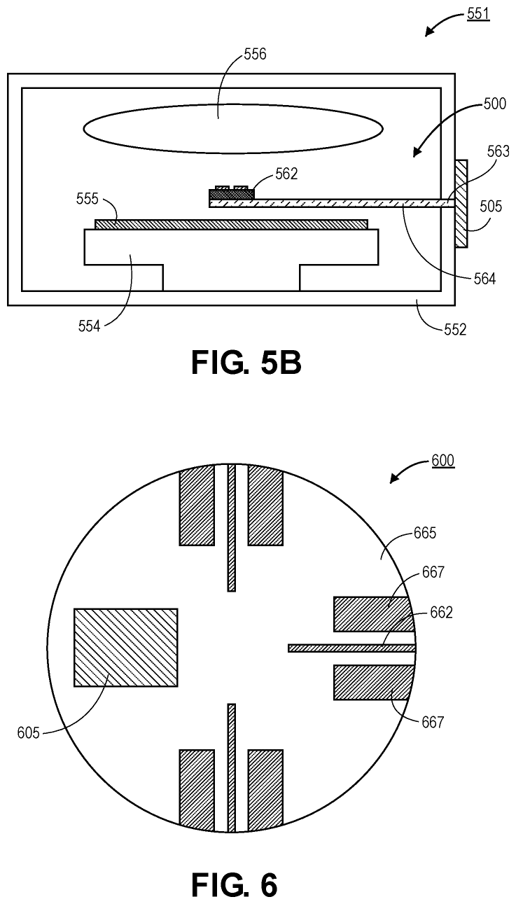

Referring now to FIG. 5A, a cross-sectional illustration of a tool 550 is shown, in accordance with an embodiment. The tool 550 may be a semiconductor processing tool in some instances. For example, the tool 550 may be a deposition chamber (e.g., chemical vapor deposition (CVD), atomic layer deposition (ALD), physical vapor deposition (PVD), etc.), an etching chamber, a plasma treatment chamber, or the like. More generally, the tool 550 may be suitable for supporting a plasma 556.

In an embodiment, the tool 550 may comprise a chamber 552. The chamber may include inlets, exhausts, etc. (not shown) for flowing gasses into and out of the chamber. In an embodiment, the tool 550 may comprise a pedestal 554 for supporting a substrate 555. The pedestal 554 may include features for securing the substrate 555 (e.g., electrostatic chucking features), as well as thermal control features (e.g., heaters, coolant loops, etc.). The substrate 555 may be a semiconductor wafer, such as a silicon wafer. Though, any substrate may be processed in the tool 550.

In an embodiment, a sensor 500 may be integrated with the tool 550. In FIG. 5A, the sensor 500 includes a resonator component 562 that is provided within the chamber 552. For example, the resonator component 562 may be provided on a sidewall of the chamber 552. Such an embodiment may be suitable for HVM environments since the resonator component 562 does not substantially interfere with processing of the substrate 556. While shown on a sidewall of the chamber 552, it is to be appreciated that the resonator component 562 may be provided on any internal surface of the chamber 552.

In an embodiment, the resonator component 562 may be coupled to a board 505 on the outside of the chamber 552 by a link 563 that passes through a wall of the chamber 552. The board 505 may comprise electrical components and circuitry similar to embodiments described in greater detail herein. For example, the electrical circuitry may include a signal generator to produce chirped pulses for enabling real time measurement of the plasma 556.

Referring now to FIG. 5B, a cross-sectional illustration of a tool 551 is shown, in accordance with an additional embodiment. The tool 551 may be similar to the tool 550 in FIG. 5A, with the exception of the sensor 500. Instead of providing the resonator component 562 on the sidewall of the chamber 552, the resonator component 556 is extended towards a center of the chamber 552 by a probe arm 564. The probe arm 564 may be coupled to the link 563 that passes through the wall of the chamber 552. Such an embodiment may be more applicable to research and development setups or other non-production monitoring environments since the probe arm 564 and the resonator component 556 may perturb the plasma 556, modifying the processing conditions of the underlying substrate 555.

Referring now to FIG. 6, a plan view illustration of a sensor 600 is shown, in accordance with an additional embodiment. In an embodiment, the sensor 600 may be integrated on a substrate 665. The substrate 665 may be sized to be inserted and removed from plasma processing chambers. As such, a single sensor 600 may be cycled through a plurality of chambers and/or tools in order to provide plasma monitoring. In an embodiment, the substrate 665 may be any suitable substrate material. In one embodiment, the substrate 665 may comprise a semiconductor material. Other embodiments may include PCB materials, metals (e.g., stainless steel, titanium, etc.), and/or the like.

In an embodiment, one or more resonators 662 may be provided on the substrate 665. The resonators 662 may be adjacent to ground planes 667 in some embodiments. While a particular structure is shown for the resonators 662, it is to be appreciated that any resonating structure may be used in the sensor 600. In an embodiment, a board 605 may be provided on the substrate 665. The board 605 may house the electrical components and structures to enable real-time monitoring of a plasma. For example, a signal generator may produce chirped pulses. Also, while shown as a discrete component, it is to be appreciated that the board 605 may be omitted. In such instances, the electrical components and/or structures may be fabricated directly on the substrate 665, especially when the substrate 665 comprises PCB materials.

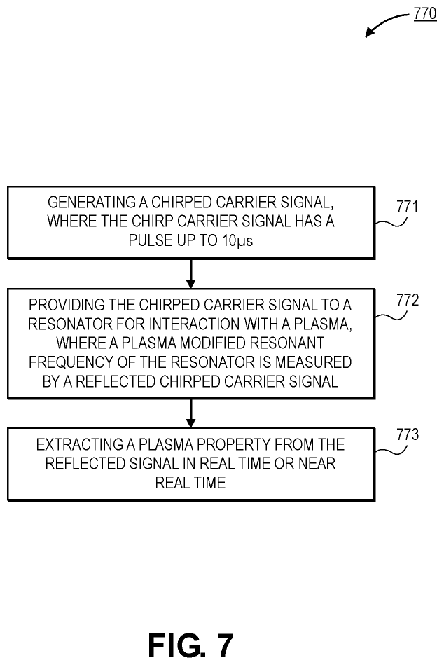

Referring now to FIG. 7, a process flow diagram of a process 770 for measuring a plasma property is shown, in accordance with an embodiment. In an embodiment, the process 770 may begin with operation 771, which comprises generating a chirped carrier signal. In an embodiment, the chirp carrier signal may have a pulse length of up to 100 ms. The chirped carrier signal may be similar to any of the chirped signals described in greater detail herein.

In an embodiment, the process 770 may continue with operation 772, which comprises providing the chirped carrier signal to a resonator for interaction with a plasma. In an embodiment, a plasma modified resonant frequency of the resonator is measured by a reflected chirped carrier signal. In an embodiment, information on plasma properties is encoded on the chirp carrier signal in the reflected signal. The resonator may be provided within a plasma chamber, similar to any of the chamber configurations described in greater detail herein.

In an embodiment, the process 770 may continue with operation 773, which comprises extracting a plasma property from the reflected signal in real time or near real time. In an embodiment, the plasma property is extracted through the use of a sampling component, such as with an ADC or the like. In an embodiment, the plasma property may be related to the frequency of the plasma that was added to the chirped carrier signal. For example, the plasma property may include a plasma electron density, an electron temperature, or the like.

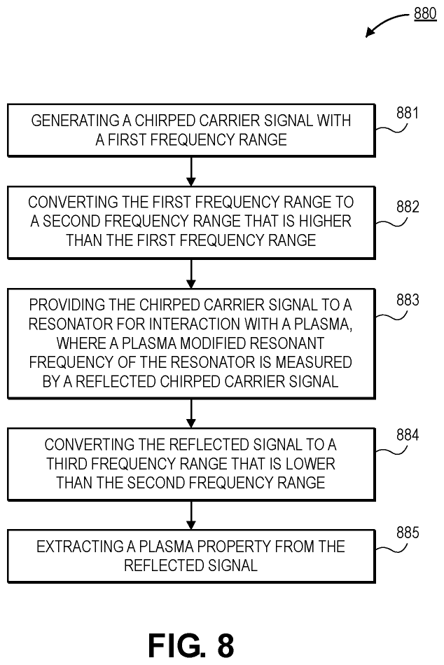

Referring now to FIG. 8, a process flow diagram of a process 880 for measuring a plasma property is shown, in accordance with an embodiment. In an embodiment, the process 880 may begin with operation 881, which comprises generating a chirped carrier signal with a first frequency range. The chirped carrier signal may be similar to any of the chirped signals described in greater detail herein. In a particular embodiment, the first frequency range may be between 0.01 GHz and 1.0 GHz.

In an embodiment, the process 880 may continue with operation 882, which comprises converting the first frequency range to a second frequency range that is higher than the first frequency range. In an embodiment, the conversion may be implemented with a mixer or the like. In an embodiment, the second frequency range may have a low frequency that is higher than the high frequency of the first frequency range. In a particular embodiment, the second frequency range may be between 9.0 GHz and 11.0 GHz.

In an embodiment, the process 880 may continue with operation 883, which comprises providing the chirped carrier signal to a resonator for interaction with a plasma. In an embodiment, a plasma modified resonant frequency of the resonator is measured by a reflected chirped carrier signal. In an embodiment, information on plasma properties is encoded on the chirped carrier signal in the reflected signal. The resonator may be provided within a plasma chamber, similar to any of the chamber configurations described in greater detail herein.

In an embodiment, the process 880 may continue with operation 884, which comprises converting the reflected signal to a third frequency range that is lower than the second frequency range. For example, a high frequency of the third frequency range may be lower than a low frequency of the second frequency range. In some embodiments, the third frequency range may be similar or the same as the first frequency range. In an embodiment, the conversion to the third frequency range may be implemented with a mixer or the like. In some embodiments, the mixer used in operation 882 may be coupled to the mixer used in operation 884 through a PLL or the like.

In an embodiment, the process 880 may continue with operation 885, which comprises extracting a plasma property from the reflected signal in real time or near real time. In an embodiment, the plasma property is extracted through the use of a sampling component, such as with an ADC or the like. In an embodiment, the plasma property may be related to the change in resonant frequency due to the resonators interaction with the plasma that is measured by the chirped carrier signal. For example, the plasma property may include a plasma electron density, an electron temperature, or the like.

In the embodiments described in greater detail herein, applications including plasma monitoring are explained in detail. However, it is to be appreciated that similar circuitry may be used to determine properties of different states of matter (e.g., gasses, liquids, or solids) using dielectric spectroscopy methods.

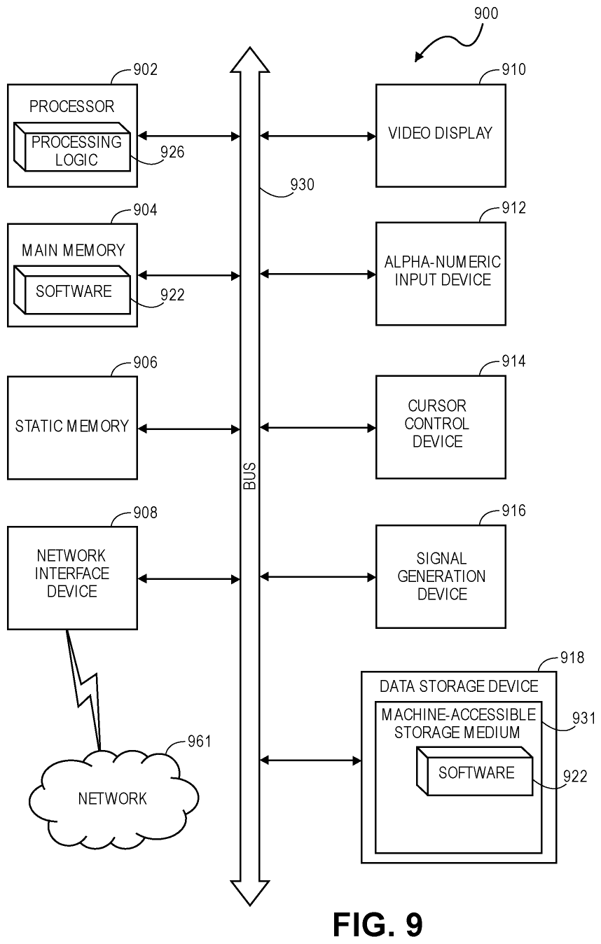

Referring now to FIG. 9, a block diagram of an exemplary computer system 900 of a processing tool is illustrated in accordance with an embodiment. In an embodiment, computer system 900 is coupled to and controls processing in the processing tool. Computer system 900 may be connected (e.g., networked) to other machines in a Local Area Network (LAN), an intranet, an extranet, or the Internet. Computer system 900 may operate in the capacity of a server or a client machine in a client-server network environment, or as a peer machine in a peer-to-peer (or distributed) network environment. Computer system 900 may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated for computer system 900, the term “machine” shall also be taken to include any collection of machines (e.g., computers) that individually or jointly execute a set (or multiple sets) of instructions to perform any one or more of the methodologies described herein.

Computer system 900 may include a computer program product, or software 922, having a non-transitory machine-readable medium having stored thereon instructions, which may be used to program computer system 900 (or other electronic devices) to perform a process according to embodiments. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, etc.), a machine (e.g., computer) readable transmission medium (electrical, optical, acoustical or other form of propagated signals (e.g., infrared signals, digital signals, etc.)), etc.

In an embodiment, computer system 900 includes a system processor 902, a main memory 904 (e.g., read-only memory (ROM), flash memory, dynamic random access memory (DRAM) such as synchronous DRAM (SDRAM) or Rambus DRAM (RDRAM), etc.), a static memory 906 (e.g., flash memory, static random access memory (SRAM), etc.), and a secondary memory 918 (e.g., a data storage device), which communicate with each other via a bus 930.

System processor 902 represents one or more general-purpose processing devices such as a microsystem processor, central processing unit, or the like. More particularly, the system processor may be a complex instruction set computing (CISC) microsystem processor, reduced instruction set computing (RISC) microsystem processor, very long instruction word (VLIW) microsystem processor, a system processor implementing other instruction sets, or system processors implementing a combination of instruction sets. System processor 902 may also be one or more special-purpose processing devices such as an application specific integrated circuit (ASIC), a field programmable gate array (FPGA), a digital signal system processor (DSP), network system processor, or the like. System processor 902 is configured to execute the processing logic 926 for performing the operations described herein.

The computer system 900 may further include a system network interface device 908 for communicating with other devices or machines. The computer system 900 may also include a video display unit 910 (e.g., a liquid crystal display (LCD), a light emitting diode display (LED), or a cathode ray tube (CRT)), an alphanumeric input device 912 (e.g., a keyboard), a cursor control device 914 (e.g., a mouse), and a signal generation device 916 (e.g., a speaker).

The secondary memory 918 may include a machine-accessible storage medium 932 (or more specifically a computer-readable storage medium) on which is stored one or more sets of instructions (e.g., software 922) embodying any one or more of the methodologies or functions described herein. The software 922 may also reside, completely or at least partially, within the main memory 904 and/or within the system processor 902 during execution thereof by the computer system 900, the main memory 904 and the system processor 902 also constituting machine-readable storage media. The software 922 may further be transmitted or received over a network 960 via the system network interface device 908. In an embodiment, the network interface device 908 may operate using RF coupling, optical coupling, acoustic coupling, or inductive coupling.

While the machine-accessible storage medium 932 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies. The term “machine-readable storage medium” shall accordingly be taken to include, but not be limited to, solid-state memories, and optical and magnetic media.

In the foregoing specification, specific exemplary embodiments have been described. It will be evident that various modifications may be made thereto without departing from the scope of the following claims. The specification and drawings are, accordingly, to be regarded in an illustrative sense rather than a restrictive sense.

What is claimed is:

1. An apparatus, comprising:
a board;
a signal generator for generating chirped signals on the board;
a first mixer on the board and electrically coupled to the signal generator;
a circulator on the board, wherein the circulator comprises a first port that is electrically coupled to the mixer, a second port that is electrically coupled to a connector, and a third port;
a second mixer on the board and electrically coupled to the third port of the circulator; and
an analog to digital converter (ADC) on the board and electrically coupled to the second mixer.

2. The apparatus of claim 1, further comprising:
a phase locked loop (PLL) synthesizer on the board and electrically coupled between the first mixer and the second mixer.

3. The apparatus of claim 1, wherein the signal generator is configured to generate the chirped signal with a pulse length up to 100 ms.

4. The apparatus of claim 1, wherein the chirped signal is a linear chirp, an exponential chirp, or a hyperbolic chirp.

5. The apparatus of claim 1, wherein the chirped signal has a frequency range with a low frequency up to 0.01 GHz and a high frequency up to 10.0 GHz.

6. The apparatus of claim 1, wherein the first mixer is configured to up-convert a signal, and wherein the second mixer is configured to down-convert the signal.

7. The apparatus of claim 1, further comprising:
a low pass filter on the board and electrically coupled between the signal generator and the first mixer and/or a high pass filter on the board and electrically coupled between the first mixer and the circulator.

8. A method for monitoring a plasma property in real time, comprising:
generating a chirped signal with a first frequency range;
converting the first frequency range to a second frequency range that is higher than the first frequency range;
providing the chirped signal to a resonator for interaction with a plasma, wherein a plasma modified resonant frequency of the resonator is measured by a reflected chirped carrier signal;
converting the reflected signal to a third frequency range that is lower than the second frequency range;
extracting a plasma property from the reflected signal.

9. The method of claim 8, wherein the chirped signal comprises a pulse length that is up to 100 ms.

10. The method of claim 8, wherein the plasma property is a plasma electron density and/or an electron temperature.

11. The method of claim 8, wherein the resonator is a microwave resonator probe.

12. The method of claim 8, wherein the first frequency range has a low frequency up to 0.01 GHz and a high frequency up to 1.0 GHz, and wherein the second frequency range has a low frequency up to 9.0 GHz and high frequency up to 11.0 GHz.

13. The method of claim 8, wherein the chirped signal is one chirp of a series of chirps, and wherein each chirp is spaced by a duration up to 10 μs.

14. The method of claim 8, wherein the chirped signal is a linear chirp, an exponential chirp, or a hyperbolic chirp.

15. A tool, comprising:
a chamber suitable for generating a plasma;
a pedestal within the chamber for supporting a substrate; and
a sensor at least partially within the chamber for measuring plasma properties, wherein the sensor comprises:
a resonator or transmission line; and
RF circuitry coupled to the resonator, wherein the RF circuitry is configured to generate chirped pulses that are fed to the resonator.

16. The tool of claim 15, wherein the resonator is provided along a wall of the chamber, and wherein the RF circuitry is coupled to the resonator through a link that passes through the wall of the chamber.

17. The tool of claim 15, wherein the sensor is integrated into a substrate that is supported on the pedestal.

18. The tool of claim 15, wherein the RF circuitry comprises:
a board;
a direct digital synthesizer (DDS) on the board;
a first mixer on the board and electrically coupled to the DDS;
a circulator on the board, wherein the circulator comprises a first port that is electrically coupled to the mixer, a second port that is electrically coupled to a connector, and a third port;
a second mixer on the board and electrically coupled to the third port of the circulator; and
an analog to digital converter (ADC) on the board and electrically coupled to the second mixer.

19. The tool of claim 15, wherein the sensor is configured to measure a frequency of the plasma generated within the chamber using the transmission line or a resonant frequency shift of the resonator induced by interaction with a plasma.

20. The tool of claim 19, wherein the frequency of the plasma or the resonant frequency shift are used to measure plasma properties.
